(19) United States
(12) Patent Application Publication
(10) Pub. No.: US 2023/0178653 A1
(43) Pub. Date: Jun. 8, 2023

(54) GATE ALL AROUND SEMICONDUCTOR DEVICE WITH STRAINED CHANNELS

(71) Applicant: International Business Machines Corporation, Armonk, NY (US)

(72) Inventors: SHOGO MOCHIZUKI, Mechanicville, NY (US); Nicolas Loubet, GUILDERLAND, NY (US)

(21) Appl. No.: 17/542,377

(22) Filed: Dec. 4, 2021

(51) Int. Cl. H01L 29/786; H01L 29/06; H01L 29/66; H01L 29/78

(52) U.S. Cl. CPC H01L 29/78618; H01L 29/0653; H01L 29/66545; H01L 29/66553; H01L 29/66742; H01L 29/78696; H01L 29/7848; H01L 29/42392

(57) ABSTRACT

A GAA (gate-all-around) semiconductor device includes a first source/drain region comprising an epitaxially grown first buffer layer disposed in contact with first device channel inner spacers and a device substrate, and an epitaxially grown first source/drain disposed adjacent to the first buffer layer. The device also includes a second source/drain region comprising an epitaxially grown second buffer layer disposed in contact with second device channel inner spacers and the device substrate, and an epitaxially grown second source/drain disposed adjacent to the second buffer layer. The first source/drain region and the second source/drain region are disposed on opposing sides of a device gate structure. The device gate structure comprising semiconductor nanosheet channels disposed between the first source/drain region and the second source/drain region.

### BACKGROUND

The disclosure relates generally to gate-all-around (GAA) semiconductor devices. The disclosure relates particularly to GAA devices having strained channels.

GAA nanosheet transistor structures enable downscaling of semiconductor architectures. GAA semiconductor devices include transistor structures having nanosheet channels between transistor source and drain regions. The transistor gates include conductive material surrounding the nanosheet channels.

### SUMMARY

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later.

In one aspect, a GAA (gate-all-around) semiconductor device includes a first source/drain region comprising an epitaxially grown first buffer layer disposed in contact with first device channel inner spacers and a device substrate, and an epitaxially grown first source/drain disposed adjacent to the first buffer layer. The device also includes a second source/drain region comprising an epitaxially grown second buffer layer disposed in contact with second device channel inner spacers and the device substrate, and an epitaxially grown second source/drain disposed adjacent to the second buffer layer. The first source/drain region and the second source/drain region are disposed on opposing sides of a device gate structure. The device gate structure comprising semiconductor nanosheet channels disposed between the source region and the drain region.

In one aspect, a GAA (gate-all-around) semiconductor device includes a first source/drain region comprising an epitaxially grown first buffer layer disposed in contact with first device channel inner spacers and a device substrate, and an epitaxially grown first doped semiconductor source/drain disposed adjacent to the first buffer layer. The device also includes a second source/drain region comprising an epitaxially grown second buffer layer disposed in contact with second device channel inner spacers and the device substrate, and an epitaxially grown second doped semiconductor source/drain disposed adjacent to the second buffer layer. The first source/drain region and the second source/drain region are disposed on opposing sides of a device gate structure. The device gate structure includes semiconductor nanosheet channels disposed between the source region and the drain region.

In one aspect a method of fabricating a GAA semiconductor device includes fabricating dummy gate structures upon a substrate, the dummy gate structures comprising alternating semiconductor nanosheet channel layers and sacrificial semiconductor layers, recessing a portion of a sacrificial semiconductor layer beneath a semiconductor nanosheet channel layer, disposing a semiconductor buffer layer adjacent to the substrate, the semiconductor nanosheet channel layers and the sacrificial semiconductor layers, epitaxially growing a doped semiconductor source/drain region adjacent to the semiconductor buffer layer, forming inner spacers between adjacent semiconductor nanosheet channel layers, and forming high-k metal gate-all-around contacts adjacent to the semiconductor nanosheet channel.

### BRIEF DESCRIPTION OF THE DRAWINGS

Through the more detailed description of some embodiments of the present disclosure in the accompanying drawings, the above and other objects, features and advantages of the present disclosure will become more apparent, wherein the same reference generally refers to the same components in the embodiments of the present disclosure.

FIG. 1A provides a plan view of a step in the fabrication of a semiconductor device, according to an embodiment of the invention. The Figure illustrates section lines X, and Y, associated with FIGS. 1B-14.

FIG. 1B provides cross-sectional views of a step in the fabrication of a semiconductor device, according to an embodiment of the invention. The figure illustrates stacks of alternating semiconductor nanosheet channel layers and sacrificial semiconductor nanosheet layers.

FIG. 2 provides cross-sectional views of a step in the fabrication of a semiconductor device, according to an embodiment of the invention. The figure illustrates the device after the formation of nanosheet fins and the deposition of shallow trench isolation dielectric materials.

FIG. 3 provides cross-sectional views of a step in the fabrication of a semiconductor device, according to an embodiment of the invention. The figure illustrates the device after the formation of dummy gate structures upon the nanosheet fins.

FIG. 4 provides cross-sectional views, of a step in the fabrication of a semiconductor device, according to an embodiment of the invention. The figure illustrates the device after the selective removal of portions of the nanosheet fins between dummy gate structures.

FIG. 5 provides cross-sectional views of a step in the fabrication of a semiconductor device, according to an embodiment of the invention. The figure illustrates the device after the recessing of sacrificial semiconductor layers between the semiconductor channel layers.

FIG. 6 provides cross-sectional views of a step in the fabrication of a semiconductor device, according to an embodiment of the invention. The figure illustrates the device after the epitaxial growth of a source/drain buffer layer.

FIG. 7 provides cross-sectional views of a step in the fabrication of a semiconductor device, according to an embodiment of the invention. The figure illustrates the device after the epitaxial growth of source/drain materials adjacent to the source/drain buffer layer.

FIG. 8 provides cross-sectional views of a step in the fabrication of a semiconductor device, according to an embodiment of the invention. The figure illustrates the device after the deposition of an interlayer dielectric material encapsulating the source/drain regions and the CMP to exposure the dummy gate material.

FIG. 9 provides cross-sectional views of a step in the fabrication of a semiconductor device, according to an embodiment of the invention. The figure illustrates the device after the removal of the dummy gate material such as polycrystalline silicon and the removal of the sacrificial semiconductor layers, thereby releasing the nanosheet channels of the device.

FIG. 10 provides cross-sectional views of a step in the fabrication of a semiconductor device, according to an embodiment of the invention. The figure illustrates the device after the selective etching of the nanosheet channels, thinning the center cross-section of the channels.

FIG. 11 provides cross-sectional views of a step in the fabrication of a semiconductor device, according to an embodiment of the invention. The figure illustrates the device after the removal of portions of the buffer layer disposed between the nanosheet channel layers.

FIG. 12 provides cross-sectional views of a step in the fabrication of a semiconductor device, according to an embodiment of the invention. The figure illustrates the device after the formation of inner spacers between adjacent semiconductor nanosheet channel layers.

FIG. 13 provides cross-sectional views of a step in the fabrication of a semiconductor device, according to an embodiment of the invention. The figure illustrates the device after the formation of the gate-all-around contacts adjacent to the inner spacers, nanosheet channels, and gate sidewall spacers.

FIG. 14 provides a flowchart depicting operational steps for forming semiconductor device, according to an embodiment of the invention.

### DETAILED DESCRIPTION

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SixGel-x where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not tended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations and the spatially relative descriptors used herein can be interpreted accordingly. In addition, be understood that when a layer is referred to as being “between” two layers, it can be the only layer between the two layers, or one or more intervening layers cat also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Deposition processes for the metal liner and sacrificial material include, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25 C. about 900 C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

In typical gate-all-around nanosheet structures, epitaxial growth of device source/drain regions proceeds from the semiconductor channels and the device substrate. These regions also interface with device inner spacers disposed between otherwise adjacent nanosheet channels. Such growth yields crystalline structures which lack any capacity to induce stress in the device nanosheet channels as the crystalline growth proceeds without an appropriate crystal lattice template, and the final crystalline structures have lattice defects induced by the lattice-inner spacer interfaces. Strained nanosheet channels have higher carrier mobilities than unstrained channels. The structures and associated fabrication methods of disclosed embodiments provide GAA nanosheet structures having strained (either tensile or compressive) nanosheet channels. In some embodiments, selective trimming of the nanosheet channel cross-sections yields channels having an increased level of strain from a given source/drain crystalline lattice.

In an embodiment, after formation of dummy gate structures including gate sidewall spacers and selective removal of nanosheet channels between gates, deposition of buffer layers between gates occurs. These semiconductor buffer layers provide a continuous surface covering the semiconductor channels as well as the gaps between the channels and the underlying device substrate. Epitaxial growth of the source/drain regions follows deposition of the buffer layer. Starting the epitaxial growth of the source/drain regions from the buffer layer yield defect-free S/D region crystalline lattices. The defect level can be quantified using cross-sectional TEM observations. In typical GAA structures having S/D epitaxial growth with the presence of inner spacers, dislocations/stacking faults are observed in the epi S/D region. In an embodiment, the continuous buffer layer formed before S/D epi growth yields defect-free S/D regions The S/D epitaxial region defect level should be similar to that of a FinFET device.

Following deposition of an interlayer dielectric upon the S/D regions, the dummy gate poly-crystalline silicon and SiGe sacrificial layers are removed, releasing the semiconductor nanosheet channels. Depending upon the material of the S/D regions, the released channels are subject to either compressive or tensile stresses resulting in compressive or tensile strains in the channels, enhancing the carrier mobility of the channel materials.

In an embodiment, the strain of the channels may be increased by selectively thinning the cross-section of the channel in the gate-width portion of the channel, leaving the inner-spacer portion of the channel intact. Thinning the channels reduces the cross-sectional area subject to any applied stresses, increasing the strain upon the channel materials. Formation of inner spacers and high-k metal gates follows the release and optional thinning of the channels.

Reference is now made to the figures. The figures provide schematic cross-sectional illustration of semiconductor devices at intermediate stages of fabrication, according to one or more embodiments of the invention. The figures provide a front cross-section (X), parallel to the nanosheet fins of the device, and a side cross-section (Y), perpendicular to the front cross-section and parallel to the gate structures of the device. The device provides schematic representations of the devices of the invention and are not to be considered accurate or limiting with regards to device element scale.

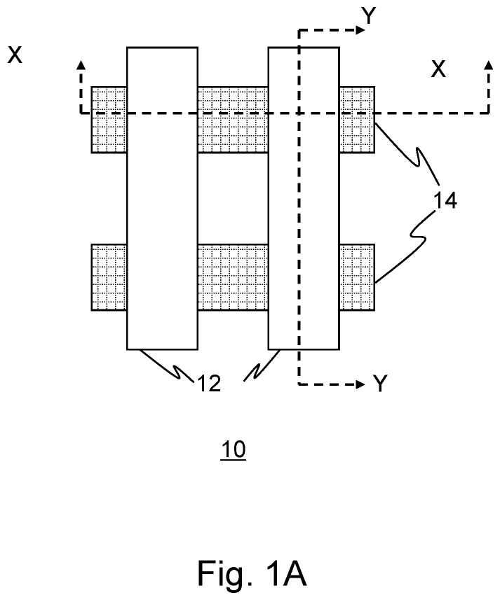

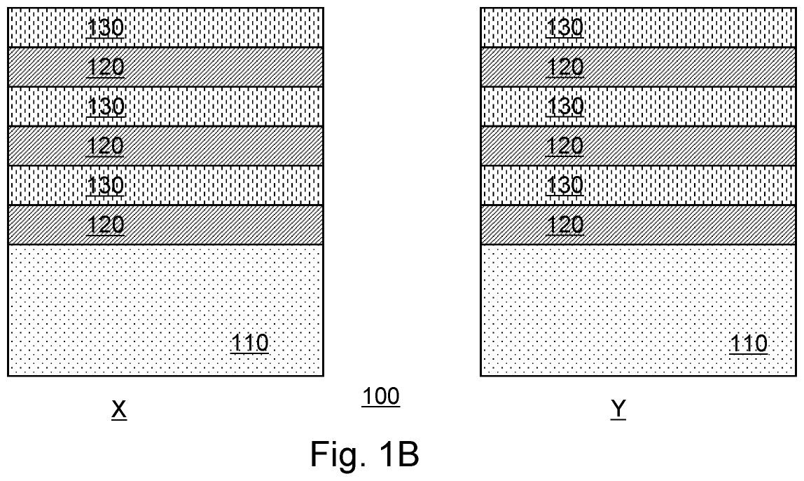

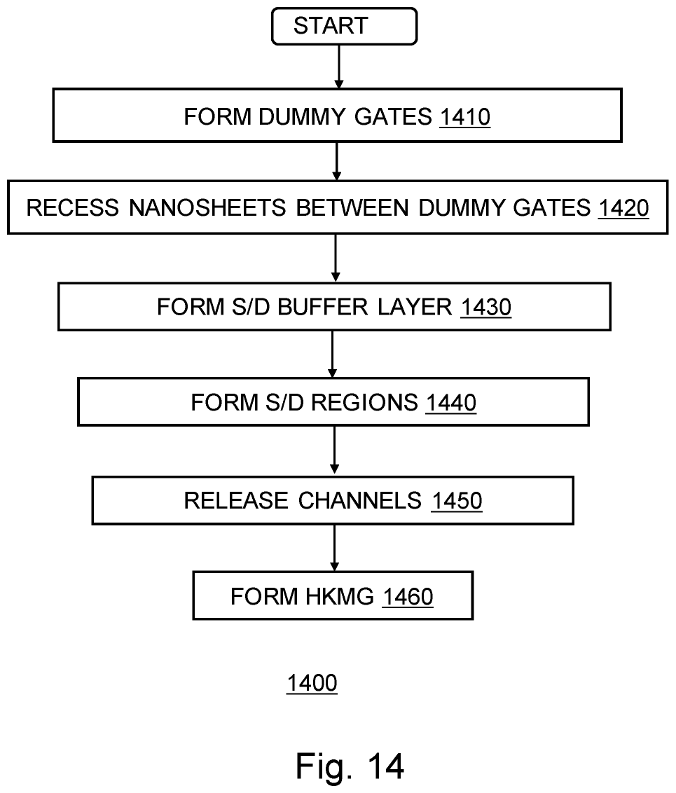

FIG. 1A provides a plan view of a device 100, according to an embodiment of the invention. The Figure illustrates the section lines X and Y, associated with the cross-sectional views of FIGS. 1B-14.

FIG. 1B provides a schematic view of a device 100 according to an embodiment of the invention following the deposition of a stack of layers for the formation of FET device nanosheets. In an embodiment, the stack includes alternating layers of epitaxially grown silicon germanium 120, and silicon 130 upon underlying Si substrate 110. Other materials having similar properties may be used in place of the SiGe and Si.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

The nanosheet stack includes a bottom-most layer of a first semiconductor material, such as SiGe and alternating layers of a second semiconductor material, such as Si. The nanosheet stack is depicted with six layers (three SiGe layers and three Si layers forming a device stack upon the underlying semiconductor substrate 110. However, any number and combination of layers can be used so long as the layers alternate between SiGe and Si to form a device upon the substrate. The nanosheet stack is depicted with the layers being in the form of nanosheets, however the width of any given nanosheet layer can be varied so as to result in the form of a nanowire, a nanoellipse, a nanowire, etc. SiGe layers 120, can be composed of, for instance, SiGe₁₅₋₃₅, examples thereof including, but not limited to SiGe₁₅, SiGe₂₀, SiGe₂₅, SiGe₃₅.

Substrate 110 can be composed of any currently known or later developed semiconductor material, which may include without limitation, silicon, germanium, silicon carbide, and those consisting essentially of one or more III-V compound semiconductors having a composition defined by the formula Alₓ₁Gaₓ₂Inₓ₃As_{y1}P_{y2}N_{y3}Sb_{y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity).

In an embodiment, each sacrificial semiconductor material layer 120, is composed of a first semiconductor material which differs in composition from at least an upper portion of the semiconductor substrate 110. In one embodiment, the upper portion of the semiconductor substrate 110 is composed of silicon, while each sacrificial semiconductor material layer 120 is composed of a silicon germanium alloy. In such an embodiment, the SiGe alloy of each sacrificial semiconductor material layer 120 has a germanium content that is greater than about 45 atomic percent germanium. In one example, the SiGe alloy of each sacrificial semiconductor material layer 120 has a germanium content between about 45 atomic percent germanium to about 70 atomic percent germanium. The first semiconductor material of each sacrificial semiconductor material layers 120 can be formed utilizing an epitaxial growth (or deposition process). In an embodiment, for a given Ge concentration x, the alloy has a Si concentration of 1−x.

Each semiconductor channel material layer 130, is composed of a second semiconductor material that has a different etch rate than the first semiconductor material of the sacrificial semiconductor material layers 120 and is also resistant to Ge condensation. The second semiconductor material of each semiconductor channel material layer 130, may be the same as, or different from, the semiconductor material of at least the upper portion of the semiconductor substrate 110. The second semiconductor material can be a SiGe alloy, provided that the SiGe alloy has a germanium content that is less than 45 atomic percent germanium, and that the first semiconductor material is different from the second semiconductor material.

In one example, at least the upper portion of the semiconductor substrate 110 and each semiconductor channel material layer 130 is composed of Si or a III-V compound semiconductor, while each sacrificial semiconductor material layer 120 is composed of a silicon germanium alloy. The second semiconductor material of each semiconductor channel material layer 130, can be formed utilizing an epitaxial growth (or deposition process).

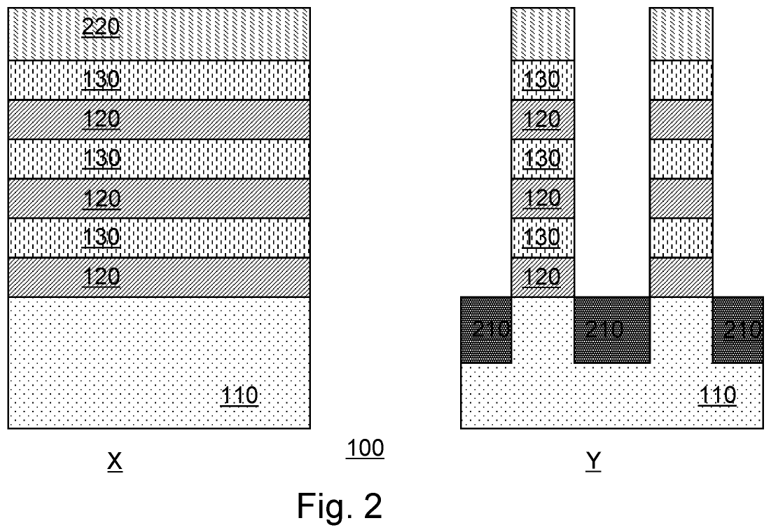

FIG. 2 illustrates device 100 following the masking, patterning, and selective etching of the stack of nanosheet layers to form individual nanosheet fin stacks. As shown in the Figure, deposition of a hardmask 220, precedes patterning and selective removal of hardmask 220, sacrificial layer 120, and channel layer 130, materials to form the device fins. In an embodiment, the stack includes alternating layers of epitaxially grown silicon germanium 120, and silicon 130. Other materials having similar properties may be used in place of the SiGe and Si. In an embodiment, reactive ion etching recesses exposed nanosheet stack portions yielding the desired nanosheet stack fins.

Exemplary hardmask 220 materials includes a nitride, oxide, an oxide-nitride bilayer, or another suitable material. In some embodiments, the hardmask 220 may include an oxide such as silicon oxide (SiO), a nitride such as silicon nitride (SiN), an oxynitride such as silicon oxynitride (SiON), combinations thereof, etc. In some embodiments, the hardmask 220 is a silicon nitride such as Si₃N₄.

In an embodiment, the etching proceeds beyond the upper surface of substrate 110, into substrate 110. Deposition of a shallow trench isolation material 210, such as silicon dioxide, or any suitable combination of multiple dielectric materials (e.g., silicon nitride and silicon oxide), occurs after the formation of shallow trench isolation (STI) regions 210 between nanosheet stack circuit elements of the device. Following such deposition, chemical mechanical planarization (CMP) processes smooth the upper surface of the deposited oxide in preparation for the subsequent fabrication steps. An oxide recess process trims the upper surface of STI regions 210 to the level of the bottom semiconductor layer 130, and. STI regions 210 provide electrical isolation between adjacent elements of NS transistors.

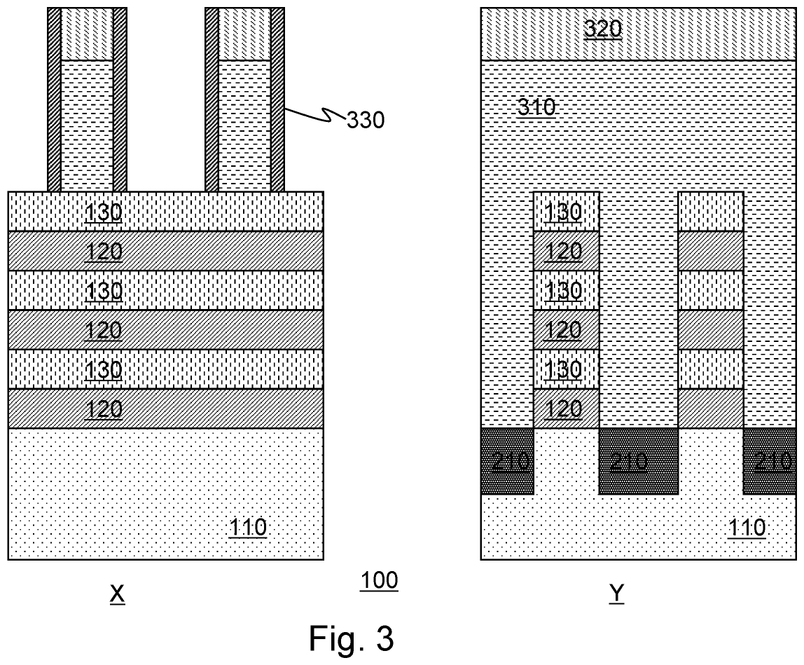

FIG. 3 illustrates device 100 following the forming of at least one dummy gate structure on the nanosheet stack. Two dummy gates are shown however any number of gates can be formed. Dummy gate structures can be formed by depositing a dummy gate material 310 over the nanosheet stack. “Depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation. The dummy gate material can be, for example, a thin layer of oxide, followed by polycrystalline silicon, amorphous silicon or microcrystal silicon. After that, a hardmask layer 320 is deposited over the dummy gate, followed by lithographic patterning and masking and selective etching processes.

Hard mask 320 includes a nitride, oxide, an oxide-nitride bilayer, or another suitable material. In some embodiments, the hardmask 320 may include an oxide such as silicon oxide (SiO), a nitride such as silicon nitride (SiN), an oxynitride such as silicon oxynitride (SiON), combinations thereof, etc. In some embodiments, the hardmask 320 is a silicon nitride such as Si₃N₄.

FIG. 3 further illustrates device 100 following the deposition and subsequent etching, such as anisotropic etching to remove material from horizontal surfaces, of gate sidewall spacers 330 adjacent to the vertical surfaces of dummy gate materials 310 and hardmask 320. In an embodiment, gate sidewall material 330, may be the same material as hardmask 320, or may be different materials and may be comprised of any one or more of a variety of different insulative materials, such as Si₃N₄, SiBCN, SiNC, SiN, SiCO, SiO₂, SiNOC, etc. In this embodiment, after conformal deposition, selective etching, such as anisotropic reactive ion etching, removes gate sidewall spacer material 330 from horizontal surfaces of the intermediate stage of the device 100.

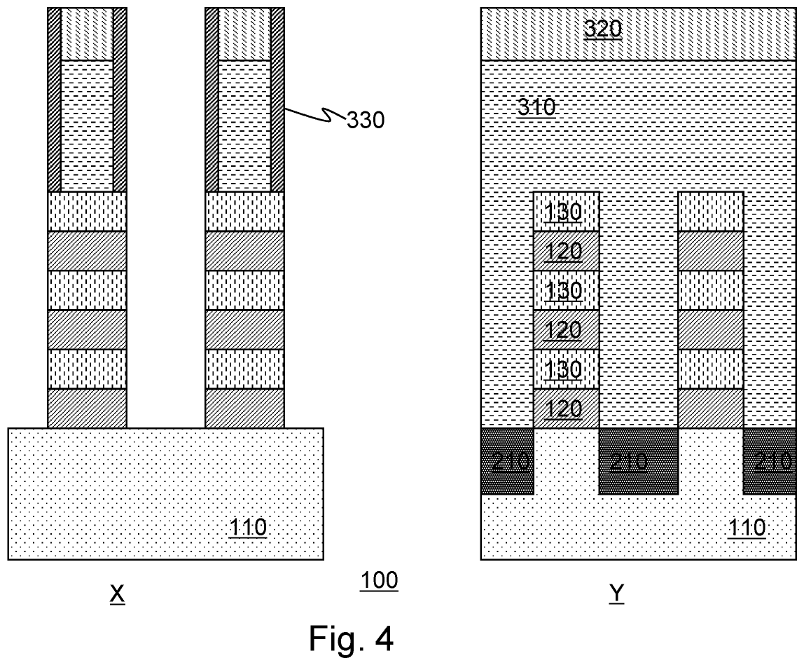

FIG. 4 illustrates device 100 following the selective masking and etching of nanosheets between dummy gate structures yielding individual gate structures. Selective anisotropic etching such as RIE, removes portions of the alternating sacrificial layers 120 and channel layers 130 from between adjacent dummy gate structures. Protective gate sidewall spacers 330 prevent damage to the dummy gate structures. The nanosheet layer portions are removed to the upper surface of the substrate 110.

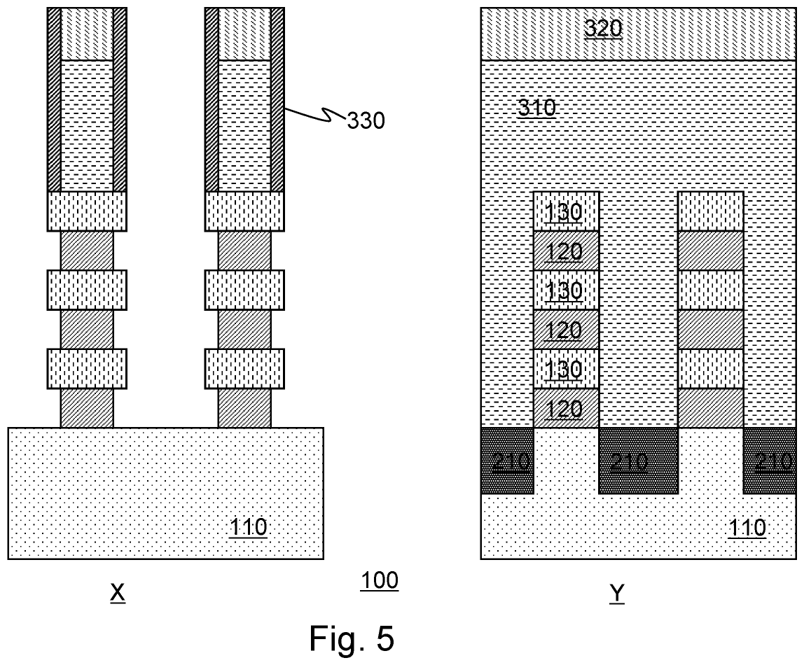

FIG. 5 illustrates device 100 following the selective recess of sacrificial layers 120 from between channel layers 130. Selective etching, such as wet etching, removes portions of the SiGe material of sacrificial layers 120 disposed between nanosheet channel layers 130 and beneath the gate sidewall spacers 330.

Etching generally refers to the removal of material from a substrate (or structures formed on the substrate) and is often performed with a mask in place so that material may selectively be removed from certain areas of the substrate, while leaving the material unaffected, in other areas of the substrate.

There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching.

After generally etching the nanosheet stack between otherwise adjacent dummy gates, a selective etching of SiGe layers 120 of the nanosheet stack removes portions of the layers which are underneath gate sidewall spacers 330.

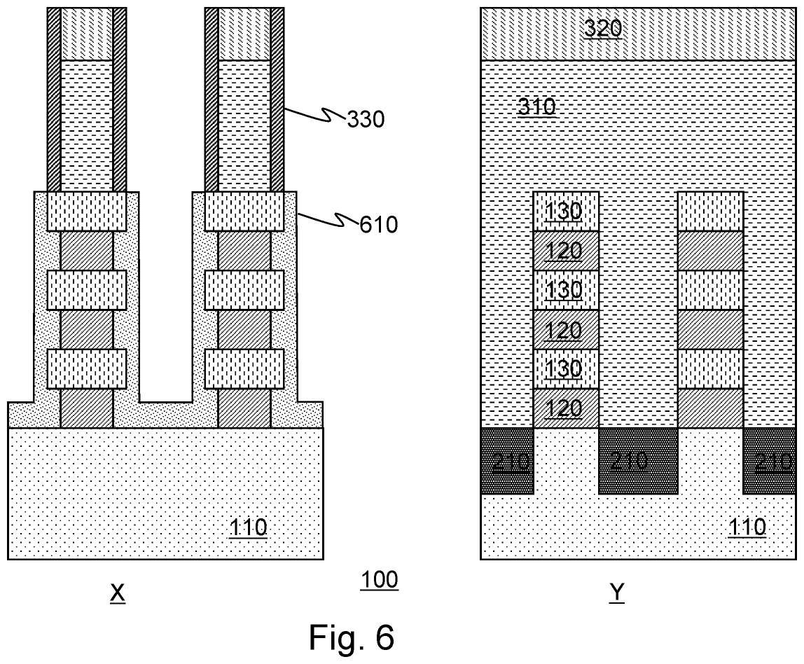

FIG. 6 illustrates device 100 following the epitaxial growth of a source/drain buffer layer upon the exposed surfaces of substrate 110, sacrificial layers 120, and nanosheet channels 130. In an embodiment, buffer layer 610 comprises a SiGe material having a lower Ge concentration than that of sacrificial layers 120. Buffer layer deposition pinches off the voids etched between adjacent nanosheet layers 130, and covers exposed surfaces of the substrate 110, sacrificial layers 120, and nanosheet channels 130. Buffer layer 610 may comprise doped or undoped semiconductor material.

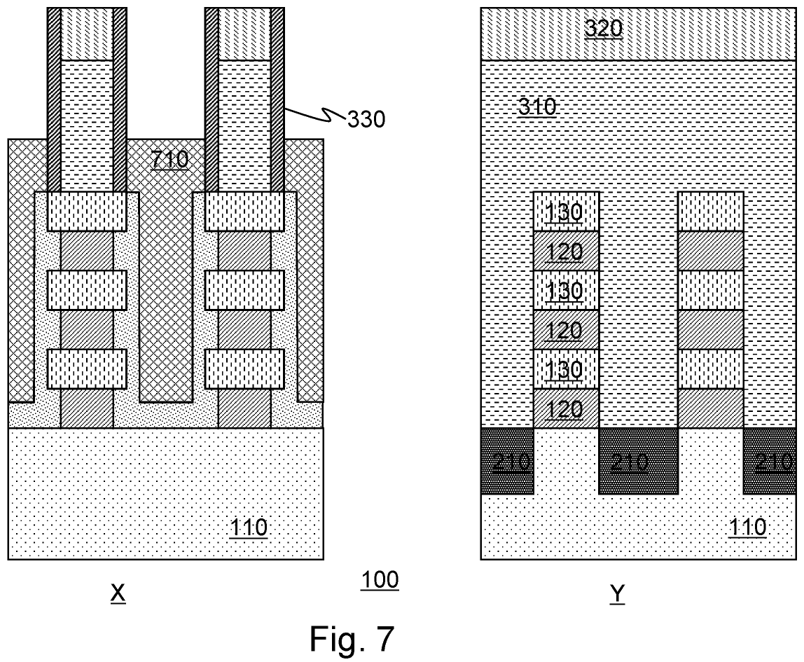

FIG. 7 illustrates device 100 following epitaxial growth of device source/drain regions 710 from the exposed surfaces of buffer layer 610. In an embodiment, S/D regions 710 comprise a doped semiconductor, such as a doped SiGe.

In an embodiment, source-drain regions 710 may be doped in situ by adding one or more dopant species to the epitaxial material. The dopant used will depend on the type of FET being formed, whether p-type or n-type. As used herein, “p-type” refers to the addition of impurities to an intrinsic semiconductor that creates deficiencies of valence electrons. In a silicon-containing semiconductor, examples of p-type dopants, i.e., impurities, include but are not limited to: boron, aluminum, gallium and indium. As used herein, “n-type” refers to the addition of impurities that contributes free electrons to an intrinsic semiconductor. In a silicon containing substrate, examples of n-type dopants, i.e., impurities, include but are not limited to carbon, antimony, arsenic and phosphorous.

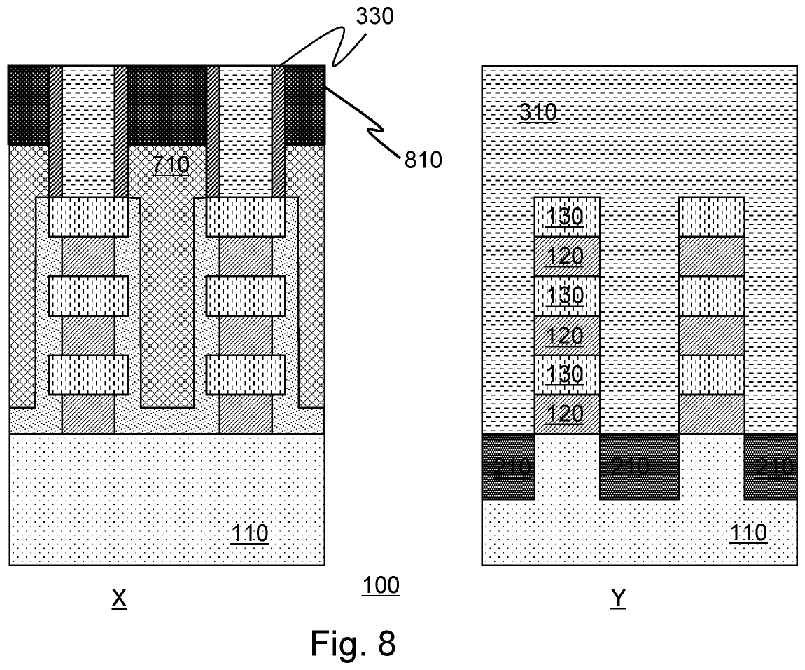

FIG. 8 illustrates device 100 following removal of dummy gate hard masks 320, and encapsulation of the dummy gates and S/D regions with an interlayer dielectric material 810, such as flowable silicon oxide. ILD 810, encapsulates the S/D regions 710, the dummy gates and gate sidewall spacers 330. Following deposition of ILD 810, chemical mechanical planarization (CMP) processes remove hardmask 320 and polish the upper surface of the device in preparation of subsequent fabrication steps.

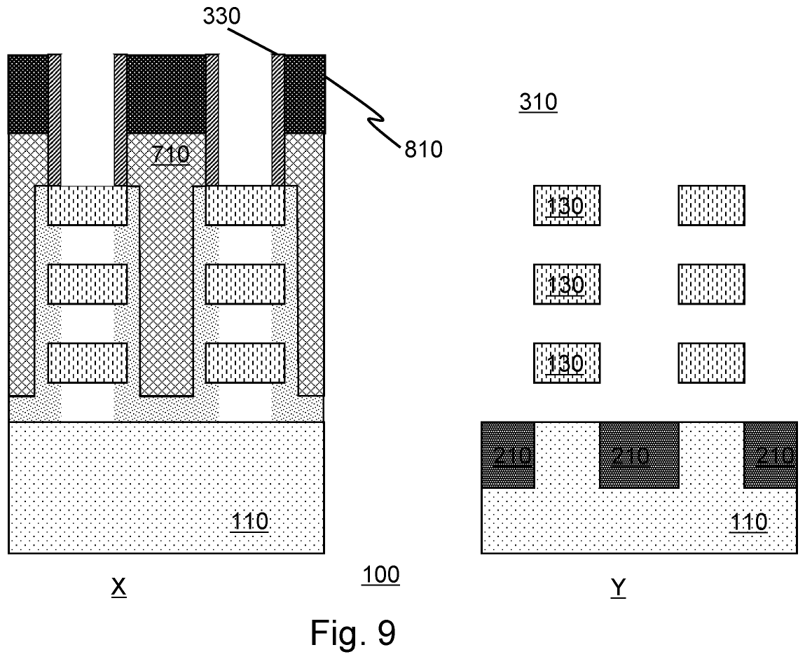

FIG. 9 illustrates device 100 following selective etching further removes the polycrystalline Si 310, of the dummy gates and selective removal of remaining sacrificial layer 120 materials by, for example, a vapor phase hydrochloric acid or chlorine trifluoride etch. The selective etch removes the SiGe of the sacrificial layers 120 while preserving the SiGe of the buffer layers 610. Removal of dummy gate material 310 and sacrificial layer material 120 releases nanosheet channels 130, subjecting the nanosheet channels 130 to either compressive stress or tensile stress from the buffer layer 610 and source/drain regions 710. S/D regions 710 of PFET devices tend to apply compressive forces to nanosheet channels 130, resulting in compressive strain in the channels 130. NFET doped S/D regions tend to subject the nanosheet channels 130 to tensile stress yielding tensile strained nanosheet channels. Straining the Si materials of the nanosheet channels 130 tends to increase the carrier mobility of the channel material enhancing the performance of the NFET and PFET devices. In an embodiment, a compressive strain applied to the channels 130 enhances the carrier mobility for pFET devices. In an embodiment, a tensile strain applied to the channels 130 enhances the carrier mobility for nFET devices.

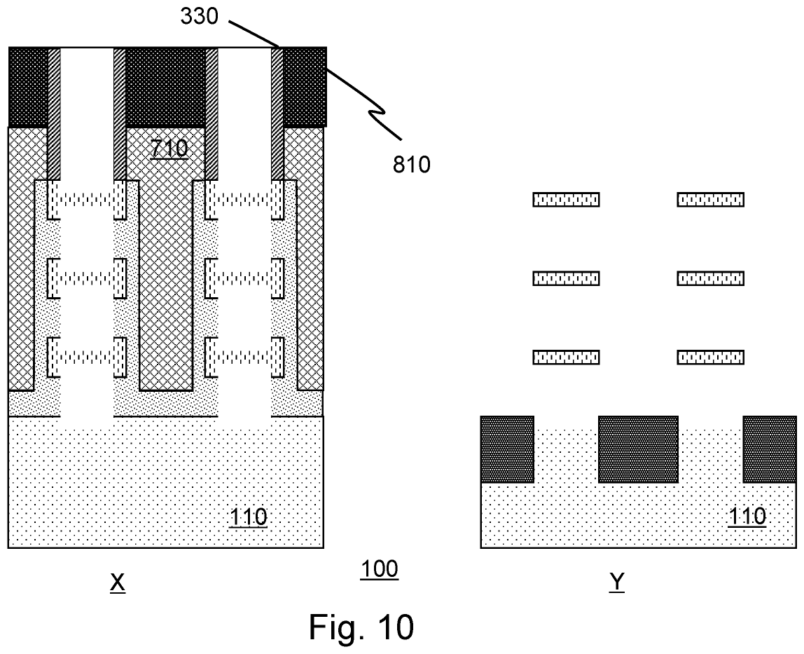

FIG. 10 illustrates device 100 following an optional thinning of nanosheet channels 130. A selective wet etch thins nanosheet channels in the gate area while preserving the channels 130 ends at the edges adjacent to the buffer layers 610 and having buffer layer 610 material disposed between channel 130 edge portions.

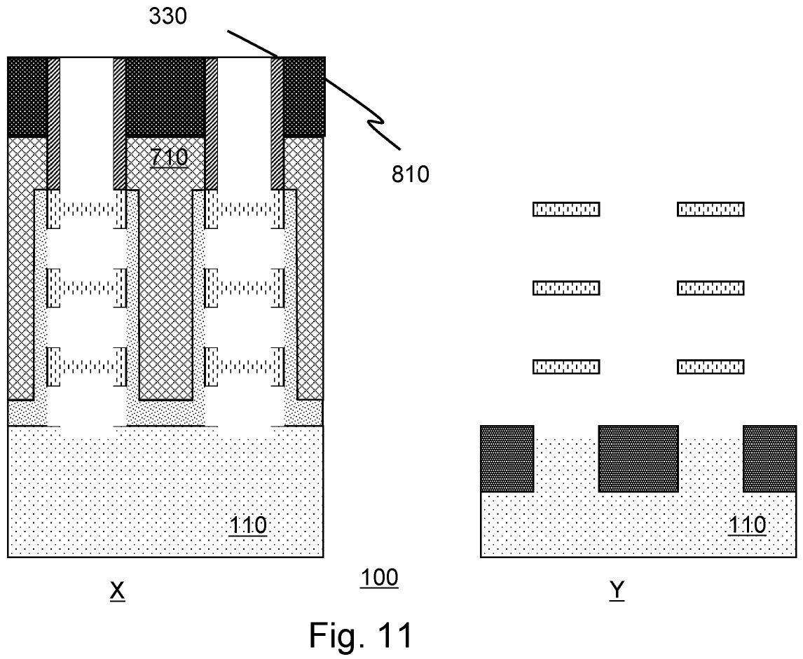

FIG. 11 illustrates device 100 following a selective etch of buffer layer 610 material from between otherwise adjacent nanosheet channels 130. A wet or vapor etch using HCl of ClF₃ selectively removes the SiGe or similar material of the buffer layers 610, from between the nanosheet channels 130.

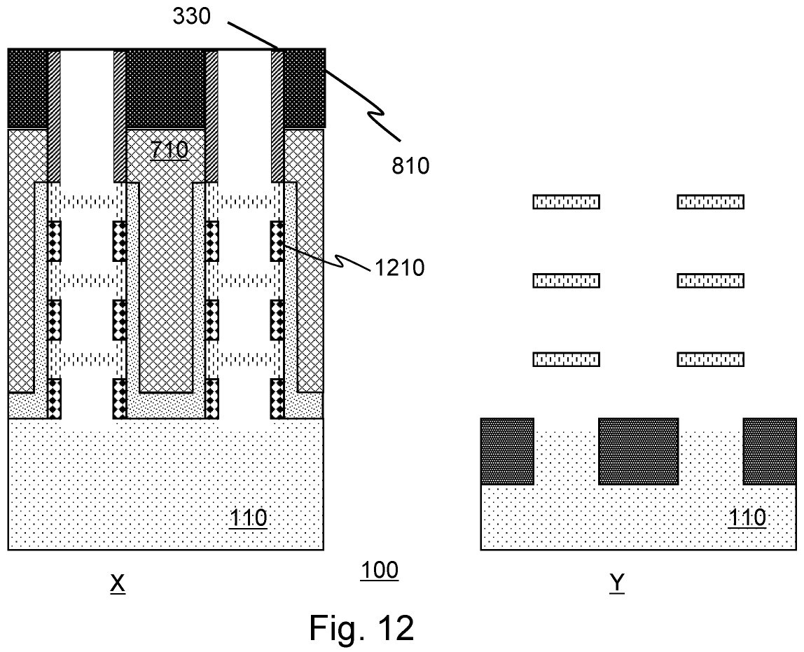

FIG. 12 illustrates device 100 following formation of device inner spacers 1210 between otherwise adjacent nanosheet channels 130. Selective etching removal follows conformal deposition, such as ALD, of a dielectric nitride material upon exposed device surfaces. Deposition of the material pinches off the gaps between otherwise adjacent nanosheet channels 130 left after selective removal of buffer layer 610 material from between the nanosheet channels 130.

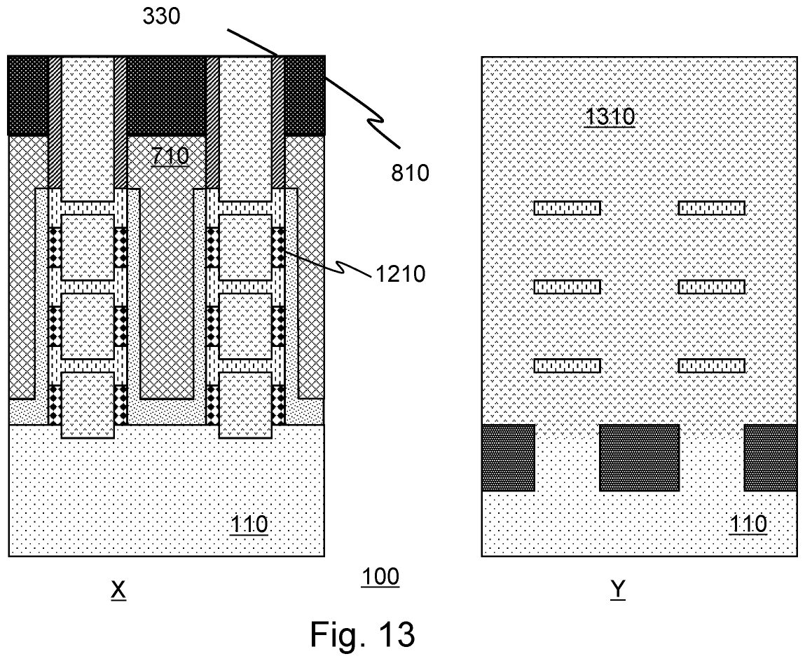

FIG. 13 illustrates device 100 following formation of high-k replacement metal gate structures in the voids left by removal of dummy gate material 310, as well as the voids left by removal of sacrificial layers 120 and then expanded by thinning the nanosheet channels 130. As shown in the Figure, a replacement metal gate structure has been formed in the void space created by removal of the dummy gate 310, and sacrificial SiGe 120 and the thinning of nanosheet channels 130. Gate structure 1310 includes gate dielectric and gate metal layers (not shown). The gate dielectric is generally a thin film and can be silicon oxide, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials may further include dopants such as lanthanum, aluminum, magnesium. Gate dielectric can be deposited by CVD, ALD, or any other suitable technique. Metal gate can include any known metal gate material known to one skilled in the art, e.g., TiN, TiAl, TiC, TiAlC, tantalum (Ta) and tantalum nitride (TaN), W, Ru, Co, Al. Metal gates may be formed via known deposition techniques, such as atomic layer deposition, chemical vapor deposition, or physical vapor deposition. It should be appreciated that a chemical mechanical planarization (CMP) process can be applied to the top surface. In an embodiment, the replacement metal gate includes work-function metal (WFM) layers, (e.g., titanium nitride, titanium aluminum nitride, titanium aluminum carbide, titanium aluminum carbon nitride, and tantalum nitride) and other appropriate metals and conducting metal layers (e.g., tungsten, cobalt, tantalum, aluminum, ruthenium, copper, metal carbides, and metal nitrides). After formation and CMP of the HKMG, the HKMG can be optionally recessed followed by a deposition and CMP of a gate cap dielectric material (not shown), such as SiN, or similar materials, completing the replacement metal gate fabrication stage for the device.

Flowchart 1400 depicts operational steps associated with the fabrication of structural embodiments of the invention. At block 1410, dummy gate structures are formed upon nanosheet stack fins upon a substrate of the device. The nanosheet stacks include sacrificial layers and nanosheet channel layers.

At block 1420, the fabrication method recesses portions of the sacrificial layers between otherwise adjacent nanosheet channel layers. The recessing forms voids for eventual inner spacer formation between the otherwise adjacent nanosheet channel layers.

At block 1430 epitaxial growth of a buffer layer upon exposed surfaces of the substrate, nanosheet channels and sacrificial layers occurs. The epitaxially grown semiconductor buffer layer serves as the base for subsequent epitaxial growth of the crystalline semiconductor source/drain regions of the device.

At block 1440, epitaxial growth of device doped S/D regions occurs between the dummy gates and adjacent to the buffer layer. Selective in-situ doping of the epitaxially grown crystalline semiconductors yield either NFET or PFET devices.

At block 1450, dummy gate materials and sacrificial nanosheet materials are removed from the device, subjecting the nanosheet channels to the stresses of the S/D crystal lattices. Such stresses and the associated channel strains may be enhanced by selective thinning of the nanosheet channels in the gate area of the channel, leaving the ends of the channels in contact with the buffer layers intact. Formation of inner spacers fills voids left between otherwise adjacent nanosheet channels after selective removal of buffer layer material present between the otherwise adjacent nanosheet channels.

At block 1460, high-k metal gates (HKMG) replace the dummy gates of the device, forming gate-all-around contacts for the devices. The HKMG surround the nanosheet channels and fill the voids left by removal of dummy gate materials, such as polycrystalline Si materials.

Following disclosed fabrication steps, additional front end of line fabrication steps occur completing the fabrication of the overall device through the addition of additional device layers and elements including external contacts and packaging.

The flowchart and block diagrams in the figures illustrate the architecture, functionality, and operation of possible implementations of systems, methods, and device fabrication steps according to various embodiments of the present invention. In this regard, each block in the flowchart or block diagrams may represent a module, segment, or portion of instructions, which comprises one or more fabrication steps for manufacturing the specified device(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A GAA (gate-all-around) semiconductor device comprising:
a first source/drain region comprising an epitaxially grown first buffer layer disposed in contact with first device channel inner spacers and a device substrate, and an epitaxially grown first source/drain disposed adjacent to the first buffer layer; and
a second source/drain region comprising an epitaxially grown second buffer layer disposed in contact with second device channel inner spacers and the device substrate, and an epitaxially grown second source/drain disposed adjacent to the second buffer layer;
wherein the first source/drain region and the second source/drain region are disposed on opposing sides of a device gate structure; and wherein the device gate structure comprising semiconductor nanosheet channels disposed between the first source/drain region and the second source/drain region.

2. The GAA semiconductor device according to claim 1, wherein the first source drain comprises a defect-free crystalline structure.

3. The GAA semiconductor device according to claim 1, wherein a nanosheet channel comprises a first cross-section having a first area adjacent to the first buffer layer and a second cross-section having a second area disposed between adjacent high-k metal gate portions of the gate structure, wherein the first area is larger than the second area.

4. The GAA semiconductor device according to claim 1, wherein a nanosheet channel comprises a compressive strained crystalline semiconductor material.

5. The GAA semiconductor device according to claim 1, wherein a nanosheet channel comprises a tensile strained crystalline semiconductor material.

6. The GAA semiconductor device according to claim 1, wherein the first buffer layer comprises a first material having a first Ge concentration, the first source/drain comprises a carbon doped Si.

7. The GAA semiconductor device according to claim 1, wherein the first buffer layer comprises a first SiGe material having a first Ge concentration, the first source/drain comprises a second SiGe material having a second Ge concentration, and wherein the second Ge concentration exceeds the first Ge concentration.

8. A GAA (gate-all-around) semiconductor device comprising:
a first source/drain region comprising an epitaxially grown first buffer layer disposed in contact with first device channel inner spacers and a device substrate, and an epitaxially grown first doped semiconductor source/drain disposed adjacent to the first buffer layer; and
a second source/drain region comprising an epitaxially grown second buffer layer disposed in contact with second device channel inner spacers and the device substrate, and an epitaxially grown second doped semiconductor source/drain disposed adjacent to the second buffer layer;
wherein the first source/drain region and the second source/drain region are disposed on opposing sides of a device gate structure, and wherein the device gate structure comprising semiconductor nanosheet channels disposed between the first source/drain region and the second source/drain region.

9. The GAA semiconductor device according to claim 8, wherein the first source drain comprises a defect-free crystalline structure.

10. The GAA semiconductor device according to claim 8, wherein a nanosheet channel comprises a first cross-section having a first area adjacent to the first buffer layer and a second cross-section having a second area disposed between adjacent high-k metal gate portions of the gate structure, wherein the first area is larger than the second area.

11. The GAA semiconductor device according to claim 8, wherein a nanosheet channel comprises a compressive strained crystalline semiconductor material.

12. The GAA semiconductor device according to claim 8, wherein a nanosheet channel comprises a tensile strained crystalline semiconductor material.

13. The GAA semiconductor device according to claim 8, wherein the first buffer layer comprises a first material having a first Ge concentration, the first source/drain comprises a carbon doped Si.

14. The GAA semiconductor device according to claim 8, wherein the first buffer layer comprises a first SiGe material having a first Ge concentration, the first source/drain comprises a second SiGe material having a second Ge concentration, and wherein the second Ge concentration exceeds the first Ge concentration.

15. A method of fabricating a GAA semiconductor device, the method comprising:
fabricating dummy gate structures upon a substrate, the dummy gate structures comprising alternating semiconductor nanosheet channel layers and sacrificial semiconductor layers;
recessing a portion of a sacrificial semiconductor layer beneath a semiconductor nanosheet channel layer;
disposing a semiconductor buffer layer adjacent to the substrate, the semiconductor nanosheet channel layers and the sacrificial semiconductor layers;
epitaxially growing a doped semiconductor source/drain region adjacent to the semiconductor buffer layer;
forming inner spacers between adjacent semiconductor nanosheet channel layers; and
forming high-k metal gate-all-around contacts adjacent to the semiconductor nanosheet channel layers.

16. The method of fabricating a semiconductor device according to claim 15, further comprising subjecting the semiconductor nanosheet channel layers to a compressive stress.

17. The method of fabricating a semiconductor device according to claim 15, further comprising subjecting the semiconductor nanosheet channel layers to a tensile stress.

18. The method of fabricating a semiconductor device according to claim 15, further comprising selectively narrowing a portion of the semiconductor nanosheet channel layers between the inner spacers.

19. The method of fabricating a semiconductor device according to claim 15, wherein the buffer layer comprises a first material having a first Ge concentration, the doped semiconductor source/drain comprises a carbon doped material.

20. The method of fabricating a semiconductor device according to claim 15, wherein the buffer layer comprises a first SiGe material having a first Ge concentration, the sacrificial semiconductor layer comprises a second SiGe material having a second Ge concentration, and wherein the second Ge concentration exceeds the first Ge concentration.
